(19) United States
(12) Patent Application Publication
(10) Pub. No.: US 2001/0020808 A1
(43) Pub. Date: Sep. 13, 2001

(54) Torsional vibrating apparatus for ultrasonic machining

(76) Inventors: Hideyuki Suzuki, Shizuoka (JP); Yasuhiro Sakamoto, Shizuoka (JP); Keisuke Monna, Shizuoka (JP)

Correspondence Address: ORUM & ROTH, 53 West Jackson Boulevard, Chicago, IL, 60604-3606, US

(21) Appl. No.: 09/791,272

(22) Filed: Feb. 22, 2001

(30) Foreign Application Priority Data
Feb. 24, 2000 (JP) 2000-048135

(51) Int. Cl. H01L 41/04

(52) U.S. Cl. 310/323.12

(57) ABSTRACT

In a torsional ultrasonic transducer for ultrasonic machining, a torsional ultrasonic transducer is structured such that a whole of a front body is integrally formed in an axially symmetrical manner, a total length thereof is set to be a half wavelength of a resonance frequency, a stepped circular column portion for adjusting a frequency is provided in the front body, and a tool attaching portion is provided in a front end portion of the front body.

### BACKGROUND OF THE INVENTION

1. Field of the Invention

The present invention relates to a torsional vibrating apparatus for ultrasonic machining which performs a cutting, grinding and drilling operation or the like of metal material, composite material, glass, ceramic or the like.

2. Description of the Related Art

A conventional torsional vibrating apparatus for ultrasonic machining is structured, as shown in FIG. 4, such that a ultrasonic transducer 1, a corn 2 and a horn 3 which have the same torsional vibration resonance frequency are connected by bolts 4 and 5, and a tool attaching portion 6 is provided in a front end portion of the horn 3. The ultrasonic transducer 1 is a bolt clamped Langevin type transducer and is structured such that a bolt 1E passing through an piezoelectric element 1C for torsional vibration and an electrode 1D is clamped with a central screw hole in a front body 1A and a back body 1B so as to hold the piezoelectric element 1C and the electrode 1D between the front body 1A and the back body 1B.

The vibrating apparatus shown in FIG. 4, a flange 2A (a position corresponding to a node of vibration) provided in the corn 2 is fixed to a table such as a cutting tool table or the like. The amplitude of the ultrasonic transducer 1 is expanded by the corn 2 and the horn 3 so as to be transmitted to a tool 7 which is attached to the tool attaching portion

In the vibrating apparatus shown in FIG. 4, the tool attaching portion 6 is provided with a female screw portion 6A, and a collet chuck 8 with slits for the tool 7 is taken into the tool attaching portion 6 so as to be taper connected by meshing a male screw portion 8A in a base end of the collet chuck 8 with the female screw portion 6A, whereby the tool 7 and the collet chuck 8 can be mounted to the tool attaching portion 6.

The conventional art has the following problems.

(1) The lengths of the ultrasonic transducer 1, the corn 2 (an amplifying transmitting body of expansion and compression of ultrasonic vibration) and the horn 3 are respectively a half (λ/2) of resonance frequency. The total length of the vibrating apparatus to which they are connected is two thirds wavelength. The length and excessive mass of the vibrating apparatus requires a large space for installing in the machining device. In particular a large-size machining device is inconvenient for small work.

(2) The operation of adjusting the respective lengths of the ultrasonic transducer 1, the corn 2 and the horn 3 to be a half wavelength at the same resonance frequency is performed by repeating a cutting operation. The shapes of the ultrasonic transducer 1, the corn 2 and the horn 3 and a measuring operation of the resonance frequency (a trial and error operation), require a lot of labor in the process.

(3) Since the diameter of the female screw portion 6A in the tool attaching portion 6 can not be large, it is not possible to strongly take the collet chuck 8 into the tool attaching portion 6 so as to achieve a taper connection, thus it is hard to improve mounting strength of the tool 7. Further, since the collet chuck 8 is rotated against the tool attaching portion 6, a sliding abrasion in the taper connected portion between the tool attaching portion 6 and the collet chuck 8 is increased.

### SUMMARY OF THE INVENTION

A first object of the present invention is to make it easy to adjust a resonance frequency and make the length of the vibrating apparatus compact.

A second object of the present invention is to easily expand the vibration amplitude of a vibrating apparatus.

A third object of the present invention is to easily and securely mount a collet chuck.

In accordance with the present invention, there is a torsional vibrating apparatus for ultrasonic processing with both a front body and a back body which hold a piezoelectric element for torsional vibration. An electrode plate is disposed therebetween using a bolt clamped Langevin type transducer torsional ultrasonic transducer, constituted by meshing a bolt passing through the piezoelectric element and the electrode plate with central screw holes on the front bodybody and the back body. The torsional ultrasonic transducer is formed in an axially symmetrical integral structure in a whole of the front body a total length thereof is a half of a resonance frequency, a stepped circular column portion for adjusting a frequency is provided in the front body, and a tool attaching portion is provided in a front end portion of the front body.

### BRIEF DESCRIPTION OF THE DRAWINGS

The present invention will be more filly understood from the detailed description given below and from the accompanying drawings which should not be taken to be a limitation on the invention, but are for explanation and understanding only.

The drawings

FIG. 1 is a schematic view showing a torsional vibrating apparatus for ultrasonic machining in accordance with the present invention;

FIGS. 2A and 2B are schematic views showing a tool attaching portion of the torsional vibrating apparatus for ultrasonic machining;

FIG. 3 is a graph of an adjusting line of resonance frequency; and

FIG. 4 is a schematic view showing a conventional embodiment.

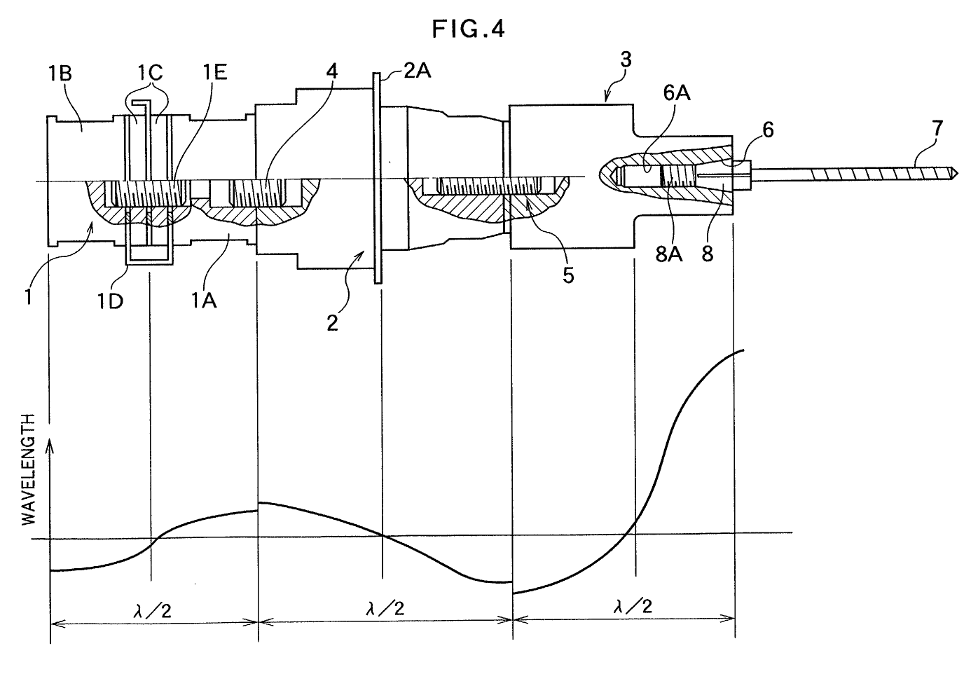

### DESCRIPTION OF THE PREFERRED EMBODIMENTS

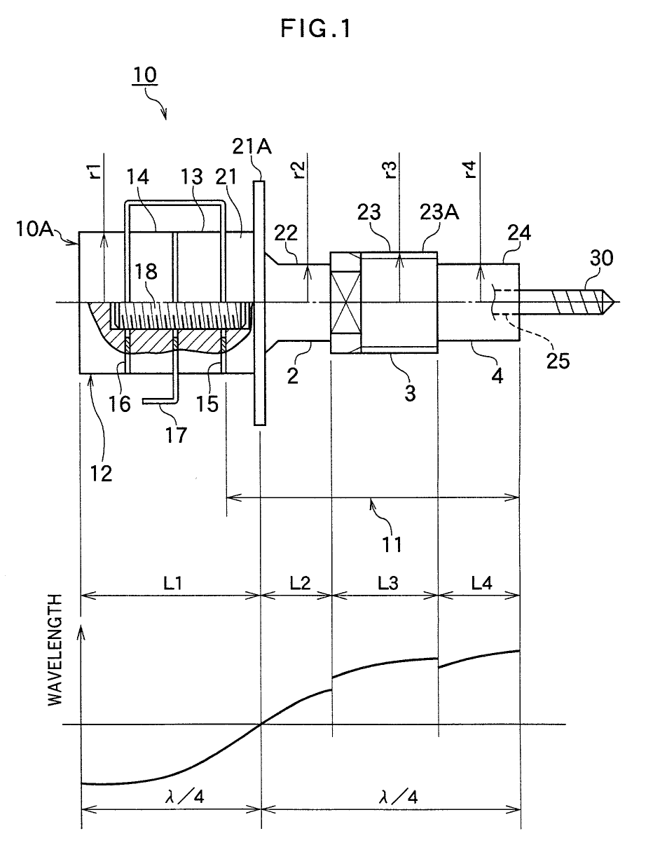

A torsional vibrating apparatus for ultrasonic machining 10 is constituted by a torsional bolt clamped Langevin type ultrasonic transducer 10A, as shown in FIG. 1. The torsional ultrasonic transducer 10A is structured such that a bolt 18 passing through torsional vibrating piezoelectric elements 13 and 14 and electrode plates 15, 16 and 17 is clamped with central screw holes in a front body 11 and a back body 12 in such a manner as to hold the piezoelectric elements 13 and 14 and the electrode plates 15, 16 and 17 between the front body 11 and the back body 12.

The front body 11 of the torsional ultrasonic transducer 10A is obtained by machining a single metal body so as to have steps, and a large-diameter portion 21 (radius r1) having the same diameter as that of the back body 12 and the piezoelectric elements 13 and 14. A middle small-diameter portion 22 (radius r2) is connected to the large-diameter portion 21 via a flange portion 21A. A stepped circular column portion 23 (radius r3) is connected to the middle small-diameter portion 22, and a front end small-diameter portion 24 (radius r4) is connected to the stepped circular column portion 23. The elements may be wholly integrally structured in an axially symmetrical manner.

The torsional ultrasonic transducer 10A is structured so that the total length thereof is a half wavelength (λ/2) of resonance frequency (λ). One may set the length between the large-diameter portion 21 of the front body 11 and the back body 12 to L1, setting respective lengths of the middle small-diameter portion 22 of the front body 11, the stepped circular column portion 23 and the front end small-diameter portion 24 to L2, L3 and L4, setting the flange portion 21A between the large-diameter portion 21 and the middle small-diameter portion 22 to a node of vibration (a fixed point of a cutting tool table or the like in the machining device) (FIG. 1), and establishing formulas L1=λ/4, L2+L3+L4=λ/4.

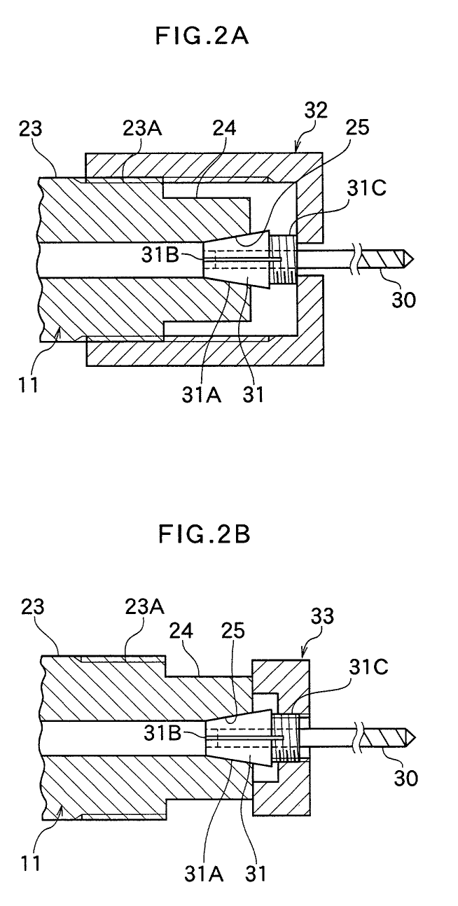

Further, the torsional ultrasonic transducer 10A is provided with a tapered hole-shaped tool attaching portion 25 in the front end, and small-diameter portion 24 of the front body 11. Then, a collet chuck with slits 31 (reference numeral 31A denotes a tapered surface and reference numeral 31B denotes a slit) to which a tool 30 such as a drill or the like is attached is taken and pressure inserted into the tool attaching portion 25. This may be firmly fixed by being subjected to a propelling force of a collet attaching device 32 clamped with a screw 23A provided in the stepped circular column portion 23 of the front body 11 to a front end surface of the collet chuck 31 in a state of being inserted to the tool attaching portion 25, as shown in FIG. 2A. The collet attaching device 32 is immediately separated from the screw 23A of the stepped circular column portion 23 after fixing the collet chuck 31 to the tool attaching portion 25, and does not generate any load for vibration. Further, when removing tool 30, the collet chuck 31 can be removed from the tool attaching portion 25 by applying a propelling force of a collet removing device 33 clamped with a screw 31C of the collet chuck 31 to the front end surface of the front end small-diameter portion 24 of the front body 11, as shown in FIG. 2B.

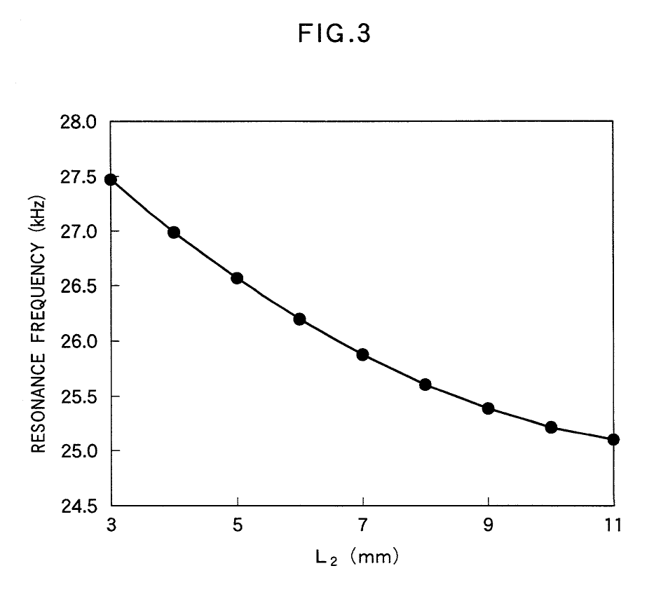

Further, the torsional ultrasonic transducer 10A can adjust the resonance frequency of the torsional ultrasonic transducer 10A in a manner as shown in FIG. 3 by setting the stepped circular column portion 23 of the front body 11 to a structure for adjusting a frequency and adjusting the length L3 thereof in accordance with a cutting operation or the like. A horizontal axis in FIG. 3 employs the length L2 of the middle small-diameter portion 22 increased by deleting the length L3 of the stepped circular column portion 23. In this case, since the torsional ultrasonic transducer 10A is structured such that the stepped circular column portion 23 is provided with the screw 23A for the collet attaching device 32 as mentioned above and the diameter (2r3) thereof can not be cut, the structure is made such that length L3 thereof is adjusted, however, the diameter of the stepped circular column portion 23 may be adjusted in accordance with a cutting operation or the like for adjusting the resonance frequency.

In the front body 11, when establishing the relations r2=r4 and r3=nr2 and setting a wavelength constant of the respective elements 21 to 24 to β (β=2πf/C, f: frequency and c: the speed of sound), a frequency condition of the torsional ultrasonic transducer 10A can be obtained by the following formula (1).

$$1 - tan β L2 ( {n}^{4} tan β L3 + tan β L4 ) - \frac{1}{{n}^{4}} tan β L3 \cdot tan β L4 = 0 \qquad ( 1 )$$

In the formula (1), when setting a constituting material of the front body 11 to a titanium alloy and establishing the relations L2+L3=20 mm, L4=10 mm and n=1.125, the resonance frequency of the torsional ultrasonic transducer 10A with respect to L2 changes as shown in FIG. 3. That is, in the torsional ultrasonic transducer 10A, it is possible to easily adjust a desired resonance frequency by deleting the length L3 of the stepped circular column portion 23 in the front body 11 and increasing the length L2 of the middle small-diameter portion 22.

Next, a description will be given of an amplitude expanding rate of the torsional ultrasonic transducer 10A.

(A) The torsional ultrasonic transducer 10A, by making the diameters (2r2, 2r3 and 2r4) of all the portions (the middle small-diameter portion 22, the stepped circular column portion 23 and the front end small-diameter portion 24) in a front end side from the flange portion 21A of the front body 11 narrower than the diameter (2r1) of the back body 12, it is possible to increase an amplitude expanding rate Mf of the torsional ultrasonic transducer 10A. The amplitude expanding rate Mf can be expressed by the following formula (2) when the torsional ultrasonic transducer 10A has the same condition as the formula (1) mentioned above and the front body 11 and the back body 12 are made of the same material.

$$\begin{matrix}Mf = {( \frac{r1}{r4} )}^{3} \cdot [ cos β L2 \cdot cos β L3 \cdot cos β L4 \times \{ ( tan β L4 + \\ { {n}^{4} tan β L3 ) + tan β L2 ( 1 + \frac{1}{{n}^{4}} tan β L3 \cdot tan β L4 ) \} ]}^{- 1}\end{matrix} \qquad ( 2 )$$

In accordance with formula (2), by making the diameters of the respective elements in a front end side of the flange portion 21A of the front body 11 narrower than the diameter of the back body 12, the amplitude expanding rate Mf is increased in proportion to the cube of a diameter ratio (r1/r4).

(B) The torsional ultrasonic transducer 10A, by making a sound impedance of the back body 12 higher than a sound impedance of the front body 11, the amplitude expanding rate Mb of the torsional ultrasonic transducer 10A can be increased. The torsional ultrasonic transducer 10A, the amplitude expanding rate Mb by the elements in a back surface side from the flange portion 21A of the front body 11, that is, the large-diameter portion 21, the piezoelectric elements 13 and 14 and the back body 12 can be obtained by the following formula (3). One may set the diameters of the respective elements 21, 13, 14 and 12 to the same diameter (2r1), setting a length, an impedance and a wavelength constant of the large-diameter portion 21 to La, Za and βa, setting a total length, an impedance and a wavelength constant of the piezoelectric elements 13 and 14 to Lb, Zb and βb, setting a length, an impedance and a wavelength constant of the back body 12 to Lc, Zc and βc, and setting K to a constant.

$$\begin{matrix}Mb = K cos β aLa \cdot cos β bLb \cdot cos β cLc \times ( tan β aLa + \\ \frac{Zc}{Za} tan β cLc + \frac{Zb}{Za} tan β bLb - \frac{Zc}{Zb} tan β aLa \cdot \\ tan β bLb \cdot tan β cLc\end{matrix} \qquad ( 3 )$$

In formula (3), the assumption is that the piezoelectric elements 13 and 14 are constituted by PZT (Za≈Zb and Lb=10 mm), the front body 11 (the large-diameter portion 21) is constituted by a titanium alloy and the back body 12 is constituted by stainless steel (SUS316). Since the sound impedance Zc of SUS316 (the back body 12) is higher than the sound impedance Za of the titanium alloy (the front body 11) (Zc≈2Za), the amplitude expanding rate Mb in the same resonance frequency is 1.2 times increased in comparison with the structure constituted by the titanium alloy in both cases of the front body 11 and the back body 12.

Therefore, in accordance with the present embodiment, the following effects can be obtained.

(1) The structure corresponding to the corn and horn in the conventional apparatus is integrally formed with the front body 11 of the torsional ultrasonic transducer 10A. The total length thereof is shortened to a half wavelength of the resonance frequency, and the tool attaching portion 25 is provided in the front end portion thereof. Accordingly, it is possible to make the total length of the vibrating apparatus 10 compact (one third of the conventional length).

(2) The stepped circular column portion 23 for adjusting the frequency is provided in the front body 11 of the torsional ultrasonic transducer 10A. Accordingly, it is possible to reduce the labor and process for adjusting the resonance frequency.

(3) Since the diameter of the front body 11 of the torsional ultrasonic transducer 10A in the front end side from the flange 21A is made narrower than the back body 12, the vibrating amplitude of the vibrating apparatus 10 can be easily expanded (to the cube of the diameter ratio) by selecting the shapes of the front body 11 and the back body 12. Accordingly, when the total length of the torsional ultrasonic transducer 10A is shortened in accordance with item (1), the vibrating amplitude can be can expanded to a level equal to or more than the conventional one.

(4) Since the sound impedance of the back body 12 of the torsional ultrasonic transducer 10A is made higher than the sound impedance of the front body 11, the vibrating amplitude of the vibrating apparatus 10 can be easily expanded by selecting the material of the front body 11 and the back body 12.

(5) The screw 23A for mounting the collet chuck 31 to the tool attaching portion 25 is provided in the stepped circular column portion 23 in the front body 11 of the torsional ultrasonic transducer 10A. Accordingly, it is possible to easily and securely mount the collet chuck 31.

As heretofore explained, embodiments of the present invention have been described in detail with reference to the drawings. However, the specific configurations of the present invention are not limited to the embodiments but those having a modification of the design within the range of the present invention are also included in the present invention.

As mentioned above, in accordance with the present invention, it is possible to make the total length of the vibrating apparatus compact and make it easy to adjust the resonance frequency.

Further, in accordance with the present invention, it is possible to easily expand the vibrating amplitude of the vibrating apparatus.

Further, in accordance with the present invention, it is possible to easily and securely attach the collet chuck.

Although the invention has been illustrated and described with respect to several exemplary embodiments thereof, it should be understood by those skilled in the art that the previous and various other changes, omissions and additions may be made to the present invention without departing from the spirit and scope thereof. Therefore, the present invention should not be understood as limited to the specific embodiment set out above, but should be understood to include all possible embodiments encompassed within a scope and equivalents thereof with respect to the features set out in the appended claims.

What is claimed is:

1. A torsional vibrating apparatus for ultrasonic processing having a front body and a back body which hold a piezoelectric element for torsional vibration and an electrode plate therebetween and using a torsional bolt clamped Langevin type ultrasonic transducer constituted by meshing a bolt passing through the piezoelectric element and the electrode plate with central screw holes on the front body and the back body,
wherein the torsional ultrasonic transducer is arranged and constructed in an axially symmetrical integral structure in a whole of the front body, a total length thereof being half of a resonance frequency, a stepped circular column portion for adjusting a frequency is provided in the front body, and a tool attaching portion is provided in a front end portion of the front body.

2. A torsional vibrating apparatus for ultrasonic processing as claimed in claim 1, wherein a diameter in a front end side of said front body is narrower than that of the back body.

3. A torsional vibrating apparatus for ultrasonic processing as claimed in claim 1, wherein a sound impedance of said back body is set to be higher than a sound impedance of the front body.

4. A torsional vibrating apparatus for ultrasonic processing as claimed in claim 2, wherein a sound impedance of said back body is set to be higher than a sound impedance of the front body.

5. A torsional vibrating apparatus for ultrasonic processing as claimed in claim 1, wherein a screw for mounting a collet chuck to the tool attaching portion is provided in the stepped circular column portion of said front body.

6. A torsional vibrating apparatus for ultrasonic processing as claimed in claim 2, wherein a screw for mounting a collet chuck to the tool attaching portion is provided in the stepped circular column portion of said front body.

7. A torsional vibrating apparatus for ultrasonic processing as claimed in claim 3, wherein a screw for mounting a collet chuck to the tool attaching portion is provided in the stepped circular column portion of said front body.

8. A torsional vibrating apparatus for ultrasonic processing as claimed in claim 4, wherein a screw for mounting a collet chuck to the tool attaching portion is provided in the stepped circular column portion of said front body.

9. A torsional vibrating apparatus for ultrasonic processing as claimed in claim 3, wherein the front body is constituted by a titanium alloy and the back body is constituted by a stainless steel.

10. A torsional vibrating apparatus for ultrasonic processing as claimed in claim 1, wherein a stepped circular column portion is formed in a front body of the torsional ultrasonic transducer, and the length or the diameter of said stepped circular column portion is adjusted so as to adjust a resonance frequency.
